(19) United States
(12) Patent Application Publication
(10) Pub. No.: US 2010/0188878 A1
(43) Pub. Date: Jul. 29, 2010

(54) SEMICONDUCTOR DEVICE THAT SUPRESSES MALFUNCTIONS DUE TO VOLTAGE REDUCTION

(75) Inventors: Hiromasa TAKEDA, Chuo-ku (JP); Kyoichi NAGATA, Chuo-ku (JP); Satoshi ISA, Chuo-ku (JP); Mitsuaki KATAGIRI, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/693,246

(22) Filed: Jan. 25, 2010

(30) Foreign Application Priority Data
Jan. 26, 2009 (JP) 2009-014375

(51) Int. Cl. G11C 5/06; G11C 5/14; G11C 7/00

(52) U.S. Cl. 365/63; 365/226; 365/205

(57) ABSTRACT

A semiconductor device includes a first pad that supplies power to sense amplifiers, a second pad that supplies power to a first circuit connected to the sense amplifiers, a third pad that receives a signal input or outputs a signal at a frequency equal to or higher than a first frequency, and a fourth pad that receives a signal input or outputs a signal at a second frequency lower than the first frequency. The first pad is arranged between and adjacent to the second pads respectively, or arranged between and adjacent to the second and fourth pads respectively. Additionally, the first pad is arranged between the third pads, which are respectively arranged on both sides of the first pad, to be adjacent to the second pad so as to hold the second pad or to be adjacent to the fourth pad so as to hold the fourth pad.

### BACKGROUND OF THE INVENTION

1. Field of the Invention

The present invention relates to a semiconductor device that has a memory circuit including storage devices.

The disclosure of U.S. Pat. No. 5,619,472 (Japanese Patent Laid-Open No. 8-139287) is incorporated herein by reference. The JEDEC STANDARD (DDR3 SDRAM Standard; JESD79-3D; (Revision of JESD79-3C, November 2008)) is incorporated herein by reference. The JEDEC STANDARD is defined by Joint Electron Device. Engineering Council Solid State Technology Association (hereinafter referred to as JEDEC).

2. Description of the Related Art

In some DRAM (Dynamic Random Access Memory) as an example of a memory device, a pad row, in which pads for electric connection to the outside are arranged in one row, is roughly divided into an I/O system and an address system. Data are input from the outside to the pads of a pad row of an I/O system or data are output from the pads of a pad row of an I/O system to the outside. Address signals are input from the outside to the pads of a pad row of an address system. An example of the DRAM is disclosed in Japanese Patent Laid-Open No. 8-139287. The DRAM disclosed in Japanese Patent Laid-Open No. 8-139287 includes a cell block in which memory cells are arranged and a sense amplifier that amplifies a signal indicating information that is stored in one memory cell selected from among the memory cells.

FIG. 1 is a plan view showing an example of the arrangement of pad rows in a chip. Chip 100 shown in FIG. 1 is a DRAM conforming to the standard of DDR3 (Double Date Rate 3). The standard is defined by JEDEC. All signal names and power supply names, functions thereof, and the like described later are matters well-known to those skilled in the art. Therefore, in this specification, detailed explanation of the signal names, the power supply names, and the functions thereof is omitted. Chip 100 includes circuits (not shown in the figure) such as a cell block and a sense amplifier. Pads and the circuits are connected by wiring not shown in the figure. The configuration of the circuits, the wiring, and the like is the same as that of the device disclosed in Japanese Patent Laid-Open No. 8-139287, although there is a difference depending on the specifications such as DDR3. Therefore, detailed explanation of the configuration is omitted. A first circuit includes a circuit for controlling the well-known cell block and sense amplifier, an input system circuit from the outside of a so-called device (semiconductor device), and an output system circuit to the outside.

As shown in FIG. 1, pad rows of an I/O system and pad rows of an address system are arranged near the center of chip 100 in a longitudinal direction of chip 100. The pad rows of the I/O system are arranged on the left side of FIG. 1 and the pad rows of the address system are arranged on the right side of FIG. 1 to correspond to the standard of the ball grid array of the DRAM.

FIG. 2A is an enlarged plan view of the pad rows of the I/O system shown in FIG. 1. FIG. 2B is an enlarged plan view of a part of the pad rows of the I/O system. In the following explanation, an expression “DQ system”, which is a general term including data input and output, is used instead of an expression “I/O system”. A pad for data input and output is referred to as DQ pad. Pads of the DQ system include, as pads of types other than the DQ, a pad for power supply voltage of the DQ system (hereinafter referred to as VDDQ) and a pad for ground potential (hereinafter referred to as VSSQ).

In pads for sense amplifier grounding as pads for supplying ground potential (VSSSA) of a sense amplifier (hereinafter referred to as VSSSA pads), since there is an inflow of electric current at the moment when a sense operation is performed, the potential VSSSA fluctuates. Therefore, concerning the arrangement of the VSSSA pads, it is necessary to satisfy two conditions: (1) the DQ pads are not arranged adjacent to the VSSSA pads; and (2) the VSSSA pads are arranged at equal intervals with respect to the pad row of the DQ system.

In FIG. 2A, the positions of the VSSSA pads are indicated by arrows. As shown in FIG. 2A, three VSSSA pads in total, i.e., the pads at both the ends of the pad row of the DQ system and one of the two pads arranged at an interval larger than intervals among the other pads in the pad row of the DQ system, are arranged, whereby the VSSSA pads are arranged at equal intervals over the entire pad row of the DQ system. Consequently, condition (2) is satisfied.

The positions of the pads arranged at an interval larger than the intervals among other pads in the pad row of the DQ system also correspond to the ends of the pad row. This is because, as shown in FIG. 2A, when the length of one side of the pad is set as a unit, the right end of the left side portion of the pad row and the left end of the right side portion of the pad row are spaced apart by about five units.

FIG. 2B is an enlarged plan view of a region surrounded by the broken line in FIG. 2A. As shown in FIG. 2B, a VDDQ pad is arranged between the VSSSA pad and the DQ pad to prevent the VSSSA pad and the DQ pad from being adjacent to each other. Consequently, condition (1) is satisfied.

The pad row of the address system is explained below.

FIG. 3A is an enlarged plan view of the pad rows of the address system shown in FIG. 1. FIG. 3B is an enlarged plan view of a part of the pad rows of the address system. In the following explanation, instead of the expression “address system”, the expression “ADD/CMD/CTRL system” is used as a general term that includes a pad into which a selected address signal will be input as a signal that selects one memory cell from among other memory cells (hereinafter referred to as ADD pad), a pad into which a command signal for determining the operation of a semiconductor device (hereinafter referred to as CMD pad) will be input, and a pad into which a control signal (hereinafter referred to as CTRL pad) will be input.

The CMD pad is a pad to which one signal from among /RAS (a row address strobe signal), /CAS (a column address strobe signal), and /WE (a write enable signal), that are defined by JEDEC, is input. Other signals (an address signal, a VREF signal, a CK signal, a CKB signal, a DQS signal, a DM signal and so on) that are described in this specification, and a plurality of pads to which these other signals are input, are defined by JEDEC in similar to the CMD pad. In addition, detailed explanation of these signals and these pads are supported by the JEDEC STANDARD.

Pads of the ADD/CMD/CTRL system include, as pads of types other than the ADD pad, the CMD pad, and the CTRL pad, a pad into which a clock signal (CK), as a reference for determining timing of input or output of various signals, will be input, a pad into which a signal (CKB), that has potential that is opposite to that of the clock signal, will be input, and a pad into which voltage, that is lower than the power supply voltage (VDD) and that is reference voltage (VREF) to be supplied to the memory cells, will be input.

As in the DQ system pad row, the VSSSA is a noise source for an input address signal, command signal, and control signal. Therefore, it is necessary to satisfy two conditions: (1) the ADD pads, the CK pads, the CKB pads, and the VREF pads are not respectively arranged adjacent to the VSSSA pads; and (2) the VSSSA pads are arranged at equal intervals with respect to the pad rows of the ADD/CMD/CTRL system.

In FIG. 3A, the positions of the VSSSA pads are indicated by arrows.

As shown in FIG. 3A, three VSSSA pads in total, i.e., the pads at both the ends of the pad row of the ADD/CMD/CTRL system and one of the two pads arranged at an interval largest among intervals of the pads in the pad row of the ADD/CMD/CTRL system, are arranged, whereby the VSSSA pads are arranged at equal intervals over the entire pad row of the ADD/CMD/CTRL system. Consequently, condition (2) is satisfied.

The positions of the pads arranged at the interval that is the largest among intervals of the pads in the pad row of the ADD/CMD/CTRL system also correspond to the ends of the pad row. This is because, as shown in FIG. 3A, when the length of one side of the pad is set as a unit, pads are spaced apart by about one unit in two places on the left side of the pad row shown in FIG. 3A and, when a section including these separated regions is referred to as the left side portion, the right end of the left side portion of the pad row and the left end of the right side portion of the pad row are spaced apart by about two units.

FIG. 3B is an enlarged plan view of a region surrounded by a broken line in FIG. 3A. As shown in FIG. 3B, a VSS pad is arranged between the VSSSA pad and the ADD pad to prevent the VSSSA pad and the ADD pad from being adjacent to each other. Consequently, condition (1) is satisfied.

As a first problem, when timing of potential fluctuation in the VSSSA and timing of the input and output of the DQ or the input of the ADD overlap, it is likely that the device misrecognizes a high level of a signal of the DQ or the ADD as a low level and misrecognizes the low level as the high level. As a second problem, deterioration in sense speed due to the potential fluctuation in the VSSSA or misdetection of the sense speed can occur. As a third problem, it is likely that distances among the pads of the VSSSA become non-uniform and bias of the VSS potential supplied to the sense amplifier occurs.

### SUMMARY

In one embodiment, there is provided a semiconductor device that includes a first pad that supplies power to a plurality of sense amplifiers, a second pad that supplies power to a first circuit connected to the plurality of sense amplifiers, a third pad that receives a signal input or outputs a signal at a frequency equal to or higher than a first frequency, and a fourth pad that receives a signal input having a second frequency lower than the first frequency or outputs a signal having the second frequency, wherein the first pad is arranged between and adjacent to a plurality of the second pads respectively arranged on both sides of the first pad, or wherein the first pad is arranged between and adjacent to the second and fourth pads respectively arranged on both sides of the first pad, and wherein the first pad is arranged between a plurality of the third pads, which are respectively arranged on both sides of the first pad, to be adjacent to the second pad so as to hold the second pad or to be adjacent to the fourth pad so as to hold the fourth pad.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view showing an example of the arrangement of pad rows in a chip;

FIG. 2A is an enlarged plan view of pad rows of an I/O system shown in FIG. 1;

FIG. 2B is an enlarged plan view of a part of the pad rows of the I/O system shown in FIG. 2A;

FIG. 3A is an enlarged plan view of pad rows of an address system shown in FIG. 1;

FIG. 3B is an enlarged plan view of a part of the pad rows of the address system shown in FIG. 3A;

FIG. 4A is a block diagram showing a configuration of a semiconductor device in Exemplary Embodiment 1;

FIG. 4B is an enlarged plan view of a region surrounded by a broken line in FIG. 4A;

FIG. 5 is a block diagram showing a configuration of a semiconductor device in Exemplary Embodiment 2;

FIG. 6A is an enlarged plan view of region R1 surrounded by a broken line shown in FIG. 5; and

FIGS. 6B and 6C are enlarged plan views of region R2 surrounded by a broken line shown in FIG. 5.

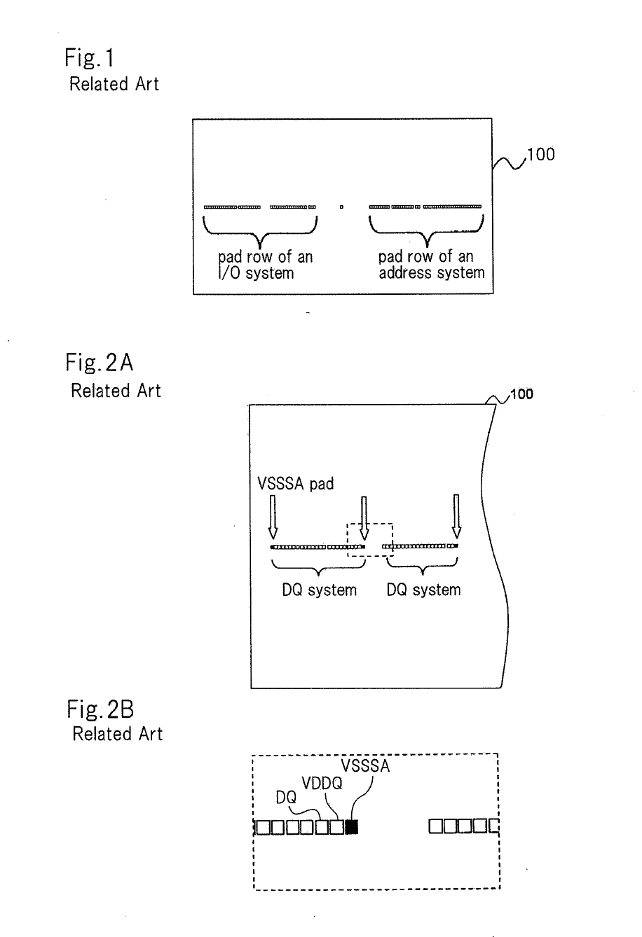

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

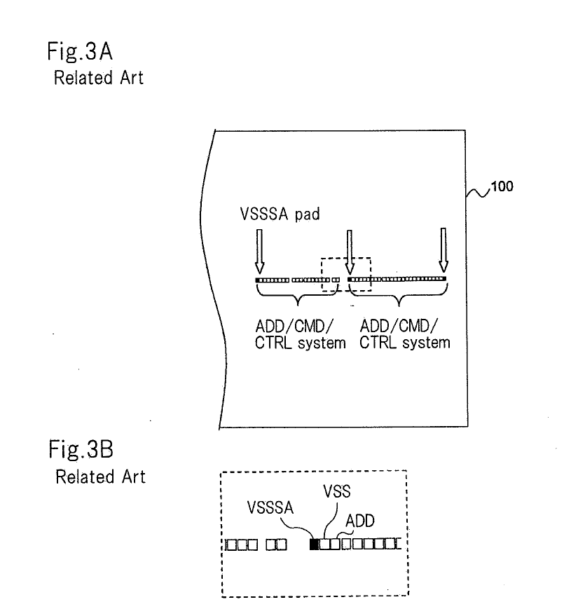

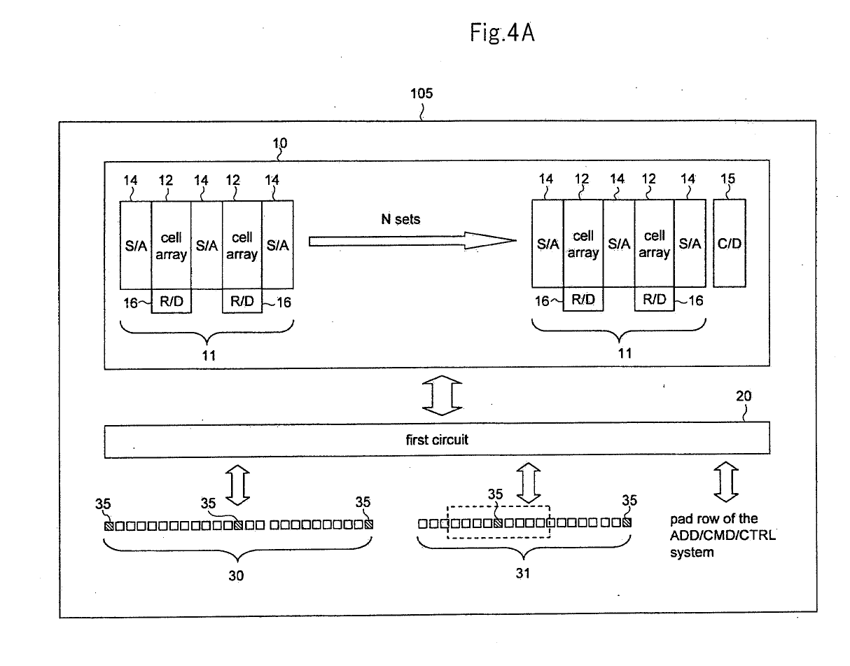

A semiconductor device according to an exemplary embodiment includes, as represented by a DRAM, memory cells, a sense amplifier, and a pad row for electrical connection to the outside including pads arranged to be expanded in a first direction. Either one pad row or a plurality of pad rows may be provided. In examples shown in FIGS. 2A, 2B, 3A, and 3B, a plurality of pad rows are arranged along one straight line.

The pad rows are not limited to be arranged on the same straight line and may be arranged in parallel. For example, concerning pad rows including first to fourth pad rows, the first and second pad rows may be arranged along one straight line and the third and fourth pad rows may be arranged parallel to the first and second pad rows and along a straight line different from the first and second pad rows. Each of at least any two pad rows among the pad rows may be arranged along each of two straight lines that cross at an arbitrary angle that is larger than 0 degrees and equal to or smaller than 90 degrees. In the following explanation, pad rows are arranged on one straight line to correspond to FIGS. 2A and 3A.

When pad rows are pad rows of a DQ system or an ADD/CMD/CTRL system, the pad rows include VSSSA pads (first pads) and signal pads into which one or more signals are input. When the pad rows are the pad rows of the DQ system, the signal pads are, for example, DQ pads (third pads). When the pad rows are the pad rows of the ADD/CMD/CTRL system, the signal pads are, for example, ADD pads, CK pads, and CKB pads (all of which are the third pads).

In this exemplary embodiment, VSSSA pads are arranged at equal intervals in a pad row not only at the ends of the pad row (pads at end most portions in a first direction in which pads are expanded) but also on the inside of the pad row (an area of pads excluding the pads at the end most portions in the first direction in which the pads are expanded). At least one pad of the other types excluding the signal pads is arranged between the VSSSA pads and the signal pads.

As explained above, according to this exemplary embodiment, even when the pads for sense amplifier grounding are arranged not only at the end but also on the inside of the pad row, since the signal pads are not adjacent to the pads for sense amplifier grounding, the influence of noise is suppressed. Therefore, even when timing of potential fluctuation of the pads for sense amplifier grounding and timing of the input and output of the DQ and the input of the ADD overlap, it is possible to prevent the device from misrecognizing a high level of a signal of the DQ or the ADD as a low level and from misrecognizing the low level as the high level.

In this exemplary embodiment, it is possible to increase the number of pads for sense amplifier grounding and to suppress fluctuation in the sense amplifier ground potential. Therefore, it is possible to suppress deterioration and misdetection of sense speed due to fluctuation in the sense amplifier ground potential. Further, in this exemplary embodiment, it is possible to arrange the pads for sense amplifier grounding at equal intervals. Therefore, distances among the pads for sense amplifier grounding become uniform and it is possible to suppress bias of the ground potential supplied to the sense amplifier.

When pads for constant voltage (fifth pads) that have a margin of voltage variation that is smaller than that of the power supply voltage and to which constant voltage is input are included in the pad row of the ADD/CMD/CTRL system, at least one pad of the other types (the second pad or a fourth pad [the fourth pad is explained later]) excluding the constant voltage pads and the signal pads is arranged between the pads for sense amplifier grounding and the constant voltage pads and between the pads for sense amplifier grounding and the signal pads.

The pads for constant voltage (the fifth pads) are, for example, VREF pads. VREF is voltage lower than the power supply voltage and has a smaller margin. The VREF pads are not arranged adjacent to the VSSSA pads because, if a voltage margin is small as in the VREF, the influence of noise is large and, if the VREF varies exceeding the voltage margin, a memory cell (a device) malfunctions. When the margin is smaller, this means that a fluctuation amount smaller than a fluctuation amount of the voltage potential of the power supply of the sense amplifier or smaller than the potential of power supplies of the other circuits is required. Specifically, in JEDEC STANDARD, a tolerance of potential fluctuation of the VDD (VDDQ) is ±0.95 times as large as the standard voltage potential. On the other hand, the VREF is 0.5±0.98 times as large as the VDD.

In the present embodiment, since third pads are not adjacent to first pads, the influence of noise is suppressed and the first problem is solved. This makes it possible to increase the number of first pads and suppress the potential for fluctuation in the first pads and the second problem is solved. Since the first problem is solved, it is possible to arrange the first pads at equal intervals and the third problem is solved.

According to the present embodiment, malfunction due to noise is suppressed and a sense amplifier characteristic is improved, whereby high-speed operation can be realized even if voltage is reduced.

Specific examples of the semiconductor device according to this exemplary embodiment are explained below.

### Exemplary Embodiment 1

A semiconductor device including the pad rows of the DQ system is explained in detail in this exemplary embodiment.

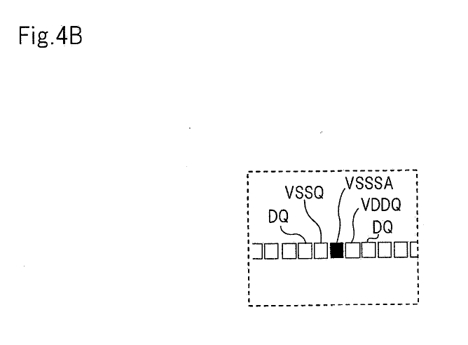

FIG. 4A is a block diagram showing a configuration of a semiconductor device in this exemplary embodiment. FIG. 4A shows an enlarged plan view of the pad rows of the DQ system. In FIG. 4A, a configuration showing a pad row of the ADD/CMD/CTRL system is omitted. FIG. 4B is an enlarged plan view of a region surrounded by a broken line in FIG. 4A.

As shown in FIG. 4A, chip 105 comprises core block 10, first circuit 20, and pad rows 30, 31 of the DQ system. Core block 10 is connected to first circuit 20 by wiring (not shown).

Core block 10 comprises a plurality of banks 11 and column decoder (C/D) 15. Banks 11, whose number is N (N is an integer which is one or more), are provided in core block 10 as shown in FIG. 4A. Each of banks 11 comprises cell arrays 12 which include a plurality of memory cells, sense amplifiers (S/A) 14, and row decoders (R/D) 16.

First circuit 20 outputs data read out by one sense amplifier 14 from among sense amplifiers 14 to the outside or inputs write data from the outside into one sense amplifier 14 from among sense amplifiers 14, or controls at least one sense amplifier 14 from among sense amplifiers 14 according to a command from the outside. In addition, first circuit 20 includes a circuit that controls address signals. In this exemplary embodiment, a configuration showing a circuit except for circuits relating to features of this invention is omitted, and detailed explanation of the circuit is omitted.

Each of pads in pad row 30 or pad row 31 of the DQ system is connected to first circuit 20 by wiring (not shown). VSSSA pads 35 are provided in pad row 30 or pad row 31 of the DQ system. VSSSA pad 35 is connected to sense amplifier 14 via first circuit 20.

As shown in FIG. 4A, the number of VSSSA pads (first pads) is increased from three to five in this exemplary embodiment. The VSSSA pads are also arranged on the inside of the pad rows to satisfy condition (2). When the VSSSA pads are simply arranged at equal intervals in the pad rows shown in FIG. 2A, the VSSSA pads could be arranged among the continuously-arranged DQ pads. In this case, condition (1) cannot be satisfied.

Therefore, in this exemplary embodiment, as shown in FIG. 4B, the VSSQ pad (the second pad) or the VDDQ pad (the second pad) is arranged between the VSSSA pad (the first pad) and the DQ pad (the third pad).

As the pads of the DQ system, in addition, there are a pad for DM (the third pad) to which a signal, that sets whether or not to enable data that will be input (a signal for masking data input), is input, a pad for DQS (the third pad) to which a signal as operation reference for timing of data input and output (referred to as DQS signal) is input, and a pad for DQSB (the third pad) to which a signal having a voltage potential that is opposite to that of the DQS signal (referred to as DQSB signal) is input. To prevent malfunction, it is desirable to prevent the pad for DM, the pad for DQS, and the pad for DQSB from being arranged adjacent to the VSSSA pad (the first pad).

On the other hand, a pad to which a signal having an operation frequency lower than that of the address signal is input may be arranged adjacent to the VSSSA pad because it is less likely that a signal input to the pad will be affected by noise even when noise occurs in the VSSSA pad.

In this exemplary embodiment, the two conditions explained in the section of the related art are satisfied for the pad rows of the DQ system, the number of VSSSA pads is increased, and the VSSSA pads are arranged at equal intervals. Therefore, even if the voltage of the device is reduced, noise that occurs in the VSSSA pads can be dispersed and the influence of noise due to the VSSSA can be suppressed.

### Exemplary Embodiment 2

A semiconductor device including the pad rows of the ADD/CMD/CTRL system is explained in detail in this exemplary embodiment.

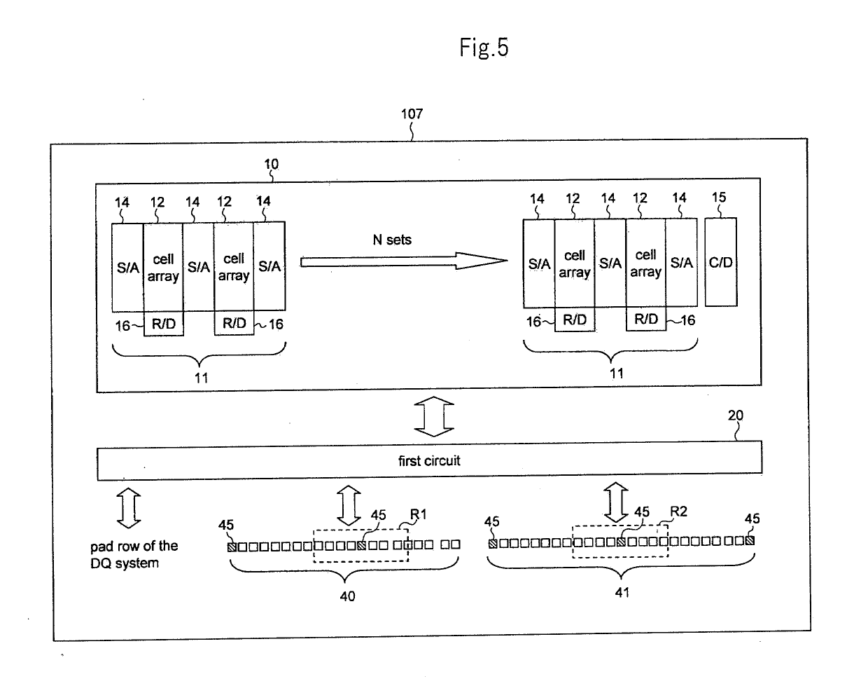

FIG. 5 is a block diagram showing a configuration of a semiconductor device in this exemplary embodiment. FIG. 5 shows an enlarged plan view of the pad rows of the ADD/CMD/CTRL system. In FIG. 5, a configuration showing a pad row of the DQ system is omitted. Components similar to Exemplary Embodiment 1 are designated the same reference numerals, and detailed descriptions thereof are omitted.

As shown in FIG. 5, chip 107 comprises core block 10, first circuit 20, and pad rows 40, 41 of the ADD/CMD/CTRL system.

Each of pads in pad row 40 or pad row 41 of the ADD/CMD/CTRL system is connected to first circuit 20 by wiring (not shown). VSSSA pads 45 are provided in pad row 40 or pad row 41 of the ADD/CMD/CTRL system. VSSSA pad 45 is connected to sense amplifier 14 via first circuit 20.

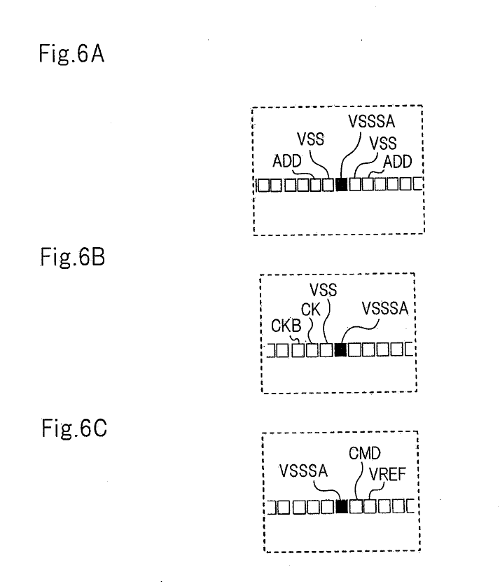

FIG. 6A is an enlarged plan view of region R1 surrounded by a broken line shown in FIG. 5. FIGS. 6B and 6C are enlarged plan views of region R2 surrounded by a broken line shown in FIG. 5.

In this exemplary embodiment, as shown in FIG. 5, the number of VSSSA pads is increased from three to five. The VSSSA pads are also arranged on the inside of the pad rows to satisfy condition (2).

When the VSSSA pads are simply arranged at equal intervals in the pad rows shown in FIG. 3A, the VSSSA pads can be arranged among the continuously-arranged ADD pads. The VSSSA pads can be arranged adjacent to CKB pads and VREF pads. In these arrangements, condition (1) cannot be satisfied.

Therefore, in this exemplary embodiment, as shown in FIG. 6A, the VSS pad is arranged between the VSSSA pad and the ADD pad. As shown in FIG. 6B, the VSS pad (the second pad) is arranged between the VSSSA pad and the CKB pad (the third pad). Further, as shown in FIG. 6C, the CMD pad is arranged between the VSSSA pad and the VREF pad. Instead of the VSS pad, the VDD pad (the second pad) may be arranged.

A CMD/CTRL pad (the fourth pad) for a signal excluding a CMD/CTRL signal having an operation frequency (a first frequency) equivalent to that of the address signal may be arranged adjacent to the VSSSA pad. This is because, even when noise occurs in the VSSSA pad, it is less likely that an input command signal will be misrecognized if the signal has an operation frequency (a second frequency) that is lower than that of the address signal. For example, a RESET pad, a CKE pad, a /CS pad (all of which are the fourth pads) may be arranged adjacent to the VSSSA pad. A signal of the pads of the DQ systems (DQ, DQS, and DM) also has the first frequency. When a standard of a data rate is a SDR (single data rate), a signal of the pads of the DQ system will have a first frequency. When the standard of the data rate is a DDR (double data rate), a signal of the pads of the DQ system will have a frequency that is twice as large as the first frequency. The CK and the CKB have the first frequency.

In this exemplary embodiment, the two conditions explained in the section of the related art are satisfied for the pad rows of the ADD/CMD/CTRL system, the number of VSSSA pads is increased, and the VSSSA pads are arranged at equal intervals. Therefore, even if the voltage of the device is reduced, noise that occurs in the VSSSA pads can be dispersed and the influence of noise due to the VSSSA can be suppressed.

When a semiconductor device includes both the DQ system and the ADD/CMD/CTRL system, both Exemplary Embodiment 1 and Exemplary Embodiment 2 may be applied to one chip.

In this exemplary embodiment, the semiconductor device is explained as the DRAM. However, the semiconductor device may be an SRAM (Static Random Access Memory) or a nonvolatile memory or may be a system LSI including a memory circuit.

The present invention can be implemented in various semiconductor devices in which the electric current consumed by sense amplifiers occupies a relatively large percentage of the electric current of the entire device. In other words, the technical idea of this application is not limited to the sense amplifier used for a memory function and the present invention can be applied to semiconductor products in general such as a CPU (Central Processing Unit), an MCU (Micro Control Unit), a DSP (Digital Signal Processor), an ASIC (Application Specific Integrated Circuit), and an ASSP (Application Specific Standard Circuit). A device to which this application is applied can be applied to semiconductor devices such as an SOC (system on chip), an MCP (multi-chip package), and a POP (package on package). A transistor used in the device according to the invention is a field effect transistor (FET) such as a MOS (Metal Oxide Semiconductor) transistor, a MIS (Metal-Insulator Semiconductor) transistor, or a TFT (Thin Film Transistor) or a bipolar transistor. Further, a semiconductor substrate is not limited to a P-type semiconductor substrate and may be an N-type semiconductor substrate or may be a semiconductor substrate having SOI (Silicon on Insulator) structure or other semiconductor substrates.

As explained above, according to this exemplary embodiment, it is possible to increase the number of pads for sense amplifier grounding while satisfying the two conditions explained in the section of the related art. Therefore, the influence of noise is reduced and signal integrity of the DQ system is improved. Bias of VSS supply from the pads to the sense amplifier is eliminated. Therefore, malfunction of the sense amplifier is prevented and sense amplifier characteristics are improved. Since the number of pads for sense amplifier grounding is increased, it is possible to suppress malfunction of the sense amplifier at low voltage. As a result, it is possible to realize low voltage and high-speed operation.

It is apparent that the present invention is not limited to the above embodiments, but may be modified and changed without departing from the scope and spirit of the invention.

What is claimed is:

1. A semiconductor device comprising:
a plurality of sense amplifiers;
a first circuit that outputs data read out by one sense amplifier from among said plurality of sense amplifiers to an outside or that inputs write data from the outside into one sense amplifier from among said plurality of sense amplifiers, or that controls at least one sense amplifier from among said plurality of sense amplifiers according to a command from the outside; and
a plurality of pads to be electrically connected to the outside, wherein
said plurality of pads include:
a first pad that supplies power to said plurality of sense amplifiers;
a second pad that supplies power to said first circuit;
a third pad that receives a signal input or outputs a signal at a frequency equal to or higher than a first frequency; and
a fourth pad that receives a signal input having a second frequency lower than said first frequency or that outputs a signal having said second frequency, wherein
said first pad is arranged between and adjacent to a plurality of said second pads respectively arranged on both sides of said first pad, or said first pad is arranged between and adjacent to said second and fourth pads respectively arranged on both sides of said first pad, and
said first pad is arranged between a plurality of said third pads, which are respectively arranged on both sides of said first pad, to be adjacent to said second pad so as to hold said second pad or to be adjacent to said fourth pad so as to hold said fourth pad.

2. The semiconductor device according to claim 1, wherein
said plurality of pads further include a fifth pad that receives a constant voltage potential other than voltage potential of a power supply for said plurality of sense amplifiers or voltage potential of a power supply for said first circuit, and
said first pad is arranged between said third pad and said fifth pad, which are respectively arranged on both sides of said first pad, to be adjacent to said second pad or said fourth pad and to hold said second pad or said fourth pad.

3. The semiconductor device according to claim 1, wherein a plurality of said first pads are arranged inside of one pad row in which pads including at least a plurality of said third pads are arranged in a first direction.

4. The semiconductor device according to claim 3, wherein a pad arranged at an end most portion of said one pad row is said first pad.

5. The semiconductor device according to claim 4, wherein a pad adjacent to said first pad arranged at the end most portion of said one pad row is said second pad.

6. The semiconductor device according to claim 4, wherein a plurality of said first pads arranged at both sides of said one pad row at the end most portions of said one pad row, and said first pad arranged inside of said one pad row, are arranged to be spaced apart at the same distance.

7. The semiconductor device according to claim 1, wherein
said first circuit is a circuit that outputs data read out by one sense amplifier from among said plurality of sense amplifiers to the outside,
said second pad is a VSSQ pad or a VDDQ pad that supplies power to said first circuit, and
said third pad is a pad of a DQ system as one pad of a DQ pad that outputs data read by one sense amplifier from among said plurality of sense amplifiers to the outside, a DQS pad as an operation reference for timing for outputting data to the outside or for inputting write data from the outside, and a DM pad that sets whether or not to enable said write data that will be input from the outside, or a combination of these pads.

8. The semiconductor device according to claim 7, wherein a plurality of said first pads are arranged inside of one pad row in which pads including a plurality of pads of said DQ system and said VSSQ pads or VDDQ pads are arranged in a first direction.

9. The semiconductor device according to claim 8, wherein a pad arranged at an end most portion of said one pad row is said first pad.

10. The semiconductor device according to claim 1, wherein
said first circuit is a circuit that controls said plurality of sense amplifiers according to a command from the outside,
said second pad is a VSS pad or a VDD pad that supplies power to said first circuit,
said third pad is a pad of an ADD/CMD/CTRL system as one pad of an ADD pad that receives an address signal input, a CMD pad that determines operation of the semiconductor device, and a CK pad that receives a clock signal input as a reference for determining timing of input or output of various signals, or a combination of these pads.

11. The semiconductor device according to claim 10, wherein a plurality of said first pads are arranged inside of one pad row in which pads including a plurality of pads of said ADD/CMD/CTRL system and said VSS pad or VDD pad are arranged in a first direction.

12. The semiconductor device according to claim 11, wherein a pad arranged at an end most portion of said one pad row is said first pad.

13. A semiconductor device comprising:
a plurality of memory cells;
a sense amplifier that amplifies a signal indicating information stored in one memory cell selected from among said plurality of memory cells; and
one or a plurality of pad rows including pads arranged in a first direction to be electrically connected to an outside, wherein
said pad row includes:
a plurality of first pads as sense amplifier grounding pads arranged at ends of said pad row and inside of said pad row and used for supplying ground potential to said sense amplifier;
a second pad that supplies power to other circuits excluding said sense amplifier;
a plurality of third pads that receive a signal input or output a signal at a frequency equal to or higher than a first frequency; and
a fourth pad that receives or outputs a signal having a second frequency lower than said first frequency, and
said second pad or said fourth pad is arranged between said sense amplifier grounding pad and said third pad, and said second pad or said fourth pad is adjacent to said sense amplifier grounding pad and said third pad.

14. The semiconductor device according to claim 13, wherein
said pad row further includes a fifth pad as a constant voltage pad that is requested to have a fluctuation amount smaller than a amount of fluctuation of voltage potential of a power supply for said sense amplifier or voltage potential of a power supply for said other circuits and that receives a fixed voltage potential input other than said voltage potential of said power supply for said sense amplifier or said voltage potential of said power supply for said first circuit, and
said second pad or said fourth pad is arranged between said sense amplifier grounding pad and said constant voltage pad, and said second pad or said fourth pad is adjacent to said sense amplifier grounding pad and said constant voltage pad.

15. The semiconductor device according to claim 14, wherein said constant voltage pad is a pad to which voltage potential lower than voltage potential of a power supply on a high potential side of said sense amplifier or voltage potential of a power supply on a high potential side of said other circuit, is applied, said voltage potential being a reference voltage to be supplied to said plurality of memory cells.

16. The semiconductor device according to claim 13, wherein said third pad is one or more pads from among an ADD pad for inputting an address signal as a signal for selecting one memory cell from among said plurality of memory cells and a pad that receives a signal at said first frequency equivalent to a frequency of said address signal.

17. The semiconductor device according to claim 13, wherein said third pad is one or more pads from among pads of a DQ pad for inputting and outputting data, a DM pad that receives a signal for setting whether or not to enable data that will be input, and a DQS pad for inputting and outputting a signal as an operation reference for data input and output.

18. The semiconductor device according to claim 13, wherein said third pad is a CK pad for inputting a clock signal as a reference for determining timing of input or output of various signals or a signal having voltage potential opposite to that of said clock signal.

19. The semiconductor device according to claim 13, wherein said second pad is one or more pads from among a pad for applying voltage potential of a power supply on a high potential side to said other circuits and a pad for applying ground potential to said other circuits.

20. The semiconductor device according to claim 13, wherein a plurality of said first pads arranged at both sides of said pad row at the end portions of said pad row, and said first pad arranged inside of said pad row, are arranged to be spaced apart at the same distance.
